(19) United States
(12) Patent Application Publication
(10) Pub. No.: US 2010/0259293 A1
(43) Pub. Date: Oct. 14, 2010

(54) Bus Terminating Part

(75) Inventor: Michael Seifried, Schwabisch-Hall (DE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: STAHL SCHALTGERATE GMBH, Waldenburg (DE)

(21) Appl. No.: 12/681,250

(22) PCT Filed: Sep. 19, 2008
(86) PCT No.: PCT/EP08/07859

§ 371 Date: Jun. 21, 2010

(30) Foreign Application Priority Data
Oct. 4, 2007 (DE) 10 2007 047 637.1

(51) Int. Cl. H03K 19/003

(52) U.S. Cl. 326/30

(57) ABSTRACT

A bus terminating component has a cylindrical housing that is designed to be inserted in a sealed manner into a PG screw connection. In the interior of the housing sits a circuit made from a bus terminating resistor and a cascade made from capacitors that are balanced by means of resistors connected in parallel. Therefore, no relevant power loss occurs on the bus terminating resistor.

### CROSS-REFERENCE TO RELATED APPLICATIONS

This application is a National Phase of PCT/EP20081007859, filed Sep. 19, 2008, which claims the benefit of German Patent Application No. 102007047637.1, filed Oct. 4, 2007, both of which are herein incorporated by reference in their entireties for all that they teach and disclose without exclusion of any part thereof.

### FIELD OF THE INVENTION

This patent disclosure relates generally to data transmission line termination and more particularly to a component for terminating such lines.

### BACKGROUND OF THE INVENTION

Data transmission lines of bus systems must be terminated at the end with an ohmic resistor whose resistance corresponds to the characteristic wave impedance of the line at the relevant transmission frequency. If the line element were left open, reflections would occur at the open end of the line and these reflections would have the result that the incoming signal would be reflected back, which interferes with communication on the bus.

A similar phenomenon occurs when the line ends are short-circuited. Here, reflection of the electrical signals is also observed. The terminating resistor can be a simple ohmic resistor. However, such installations regularly leads to problems. For reasons of regulations, especially in the field of explosion protection, it is impermissible to install an electronic component, such as a terminating resistor, with its terminal wires or extension wires affixed to the resistor, simply loose in a terminal box.

For this reason, in the past, for the comparatively small terminating resistor, a housing has been kept ready that is snapped onto the top hat rail in the installation box. The lines leading out from the housing are then connected to the bus line in a corresponding way. The mechanical size of the resistor is typically about 10 mm length and 2.53 mm diameter, while the top hat rail housing is a block-shaped housing with a width of at least 10 mm and a height of ca. 50 mm. Thus, the mechanical effort in installing such a resistor is generally is generally unreasonable given the size of the terminating resistor itself.

Modern bus systems have transitioned to transmitting the power supply energy via the data lines simultaneously. This causes further problems, however, in that the terminating resistor on the data transmission lines is now also viewed as an electrical load for the power supply voltage. For an assumed power supply voltage of 12 Volts and a terminating resistor of about 50 Ohm, a power loss of about 3 Watts occurs at the terminating resistor. The resistor must be dimensioned accordingly. In areas protected from explosions, there is also the requirement that the surface temperature of the resistor may not exceed certain limits. Accordingly, large cooling bodies must be provided in order to keep the temperature of the ohmic resistor in permissible ranges.

The disclosed principles herein are directed at least in part to overcoming one or more disadvantages of the prior art, noted or otherwise. However, it will be appreciated that the invention itself is defined by the attached claims without to regard to whether and to what extent the specifically claimed invention overcomes one or more of the noted problems in the existing technology. Moreover, it will be appreciated that any discussion herein of any reference or publication is merely intended as an invitation to study the indicated reference itself, and is not intended to replace or supplement the actual reference. To the extent that the discussion of any reference herein is inconsistent with that reference, it will be appreciated that the reference itself is conclusive as to its teachings.

### OBJECTS AND SUMMARY OF THE INVENTION

It is an object of the invention to create a bus terminating component that requires less space mechanically and that fulfills appropriate installation specifications. This object is achieved according to the invention by a bus terminating component with the features of a cylindrical housing that forms a housing interior, a stop shoulder arranged on the housing, with electrical or electronic components that are arranged in the housing interior and that are suitable for terminating a bus with low reflection, with a sealing compound that seals at least to the outside or preferably predominantly or completely fills the housing interior, and with two terminal wires leading out from the housing interior.

Further objects and advantages of the disclosed principles will be appreciated from the following detailed description and the accompanying drawings, of which:

### BRIEF DESCRIPTION OF THE DRAWINGS

FIG. 1 is an exploded view, in a partial cutaway, of the bus terminating component according to the invention in connection with a PG coupling connection; and

FIG. 2 illustrates an electrical block circuit diagram of the bus terminating component according to FIG. 1.

### DESCRIPTION OF THE PREFERRED EMBODIMENTS

The new bus terminating component is provided with a cylindrical housing that forms a housing interior. The housing itself has a stop shoulder on the outside. The housing interior holds the components that are required for terminating the line and that are connected to terminal wires leading out from the housing interior. The housing interior is filled predominantly with a sealing compound. In this way, a bus terminating component is obtained that can be inserted into a cylindrical opening in a suitable way. The voluminous housing for snapping onto a top hat rail is unnecessary. Due to the cylindrical arrangement, there is the possibility to hold the housing in a mechanically fixed way in conformance with the installation specifications, for example, in a cable entry point. Such a cable entry point can be, for example, a typical PG screw connection that is already provided in large numbers on the installation boxes or that can be inserted additionally. Furthermore, the new bus terminating component could also be affixed, e.g., to pipe or cable clamps.

The effort to be carried out by an additional PG screw connection is small compared to a housing to be snapped onto a top hat rail. The cylindrical housing is advantageously made from plastic in an embodiment of the invention. In a further embodiment of the invention, in order to simplify insertion, the housing tapers with a frustum-like shape, on each side of which the terminal wires emerge. In this way, insertion into a rubber seal of a PG screw connection is significantly simplified.

The housing can have a head at the end opposite the open end. In this way, a type of handle is created with which, for disassembly, the component can be removed from the corresponding opening in which it sits. The head is preferably arranged coaxial to the other housing. Advantageously, the housing or the head is closed on its end face such that the housing forms a blind-hole-like interior. The contact can be formed by the step in which one part of the cylindrical housing transitions into the cylindrical head.

According to another aspect of the invention, the task of the invention is to create a bus terminating component that functions without cooling devices when the power supply voltage is simultaneously provided on the data-transmission line. This task is solved according to the invention by a bus terminating component with an explosion-proof construction, with an ohmic terminating resistor whose resistance value corresponds to the characteristic wave impedance of the line to be terminated, and with at least one capacitor (31-33) lying in series with the terminating resistor.

The new bus terminating component has an ohmic terminating resistor whose resistance value is adapted to the characteristic wave impedance of the line in the relevant frequency range. In series with the bus terminating resistor there is at least one capacitor whose impedance at the frequency in question is small relative to the characteristic wave impedance. With the help of the capacitor, the direct-current voltage is isolated on the power supply line. The terminating resistor is thus loaded only with the signal energy.

The same also applies if the power supply voltage is provided as a low-frequency alternating voltage. Even if the capacitor is small in its impedance relative to the characteristic wave resistance at the transmission frequency, its impedance is still large relative to the terminating resistance at the frequency of the power supply alternating voltage. The power loss of the line terminating resistor is accordingly very small and no cooling means are required.

In order to increase the electrical safety in case the capacitor fails, advantageously several capacitors, for example three, are connected in series. For certain types of capacitors, for example, ceramic capacitors, the capacitance value is dependent on the applied voltage. In order to distribute the voltage across the capacitors uniformly, a balancing resistor lies parallel to each capacitor. The size of the balancing resistor is large relative to the resistance value of the terminating resistor, so that the power loss that occurs at the balancing resistor lies in the microwatt range, wherein, in turn, no special means are necessary for cooling.

This description of the figures explains aspects for understanding the invention. Additional details that are not described can be inferred in the conventional way from the drawings by someone skilled in the art, wherein these details, in this respect, supplement the description of the figures. It is clear that a series of modifications is possible.

The drawings are not necessarily to scale. For illustrating details, certain regions might be shown disproportionately large. In addition, the drawings are significantly simplified and do not contain details possibly present in practical construction.

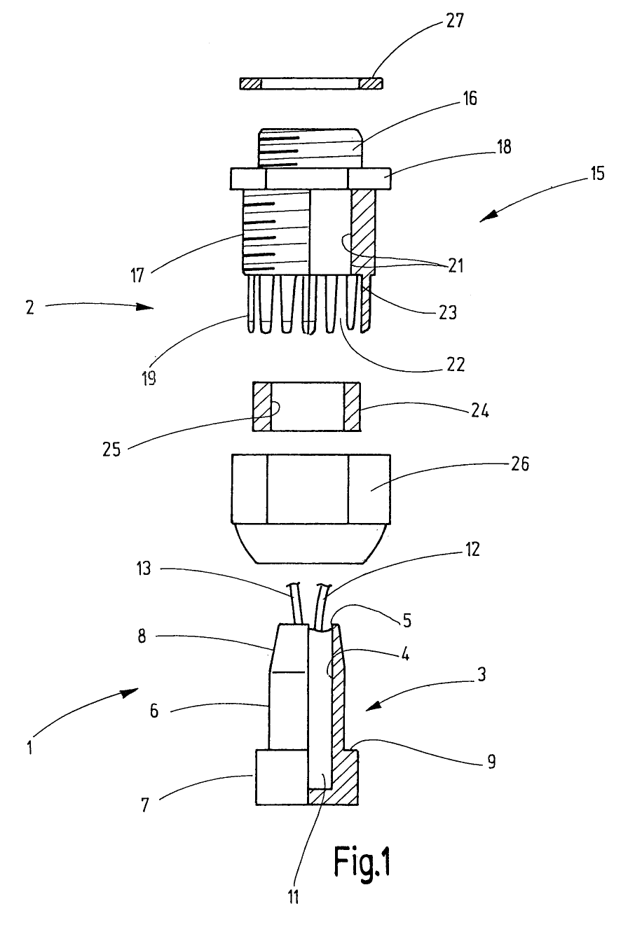

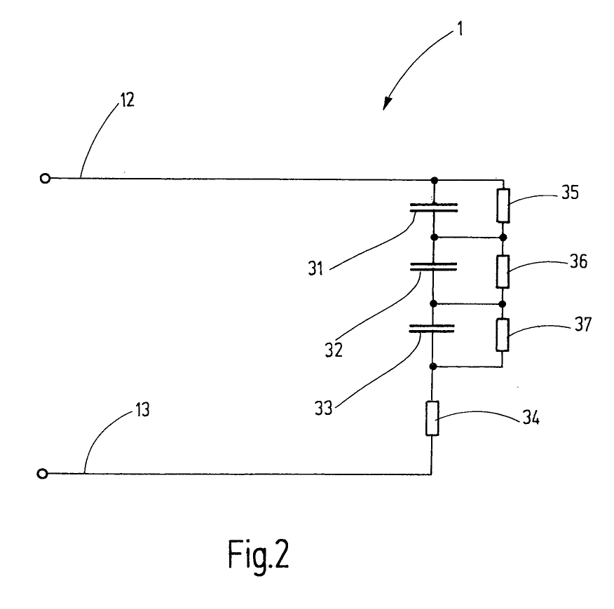

Shown in the drawing are embodiments of the subject matter of the invention. FIG. 1 shows, in a partial cutaway, exploded view, the bus terminating component according to the invention in connection with a PG coupling connection. FIG. 2 shows the electrical block circuit diagram of the bus terminating component according to FIG. 1.

FIG. 1 shows a bus terminating component 1 according to the invention in connection with a PG screw connection 2. The bus terminating component 1 is partially cut longitudinally. As can be seen, the bus terminating component 1 has a housing 3 that forms a blind-hole-like interior 4 that opens outward at 5 into a circular opening.

The outer contours of the housing 3 are combined from a first cylindrical section 6 and also a second cylindrical section 7 and a frustum-like section 8. The cylindrical section 7 has a larger diameter than the cylindrical section 6, wherein a shoulder 9 that is flat is produced with this larger cylindrical section. In addition, the cylindrical section 6 is longer than the cylindrical section 7, while the frustum-like section 8 has a length approximately corresponding to that of the cylindrical section 7.

A cylindrically smooth, continuous blind hole forms the interior 4. The electronic or electrical components, in the form of a simple, ohmic resistor or a circuit assembly as shown in FIG. 2, are located in this interior 4. The entire arrangement is filled with a sealing compound 11 in which the electrical or electronic components are contained.

Two terminal wires 12 and 13 lead out from the sealing compound 11. The entire bus terminating component 1 fulfills overall the regulations for explosion protection, because it could be regarded as being in the encapsulation ignition protection category or in the intrinsic safety ignition protection category. Construction in the flameproof enclosure ignition protection category is also possible.

The housing 3 of the bus terminating component 1 is shaped so that it can be inserted into a PG screw connection and is to be clamped in this connection. Because of this, for the sake of completeness, the PG screw connection 2 will be explained that is shown in an exploded view and that is also partially cut longitudinally.

The PG screw connection 2 includes a tubular base body 15 on which a first external threading 16 and also a second external threading 17 are constructed. The external threading 16 has a smaller diameter than the external threading 17 and is designed to be screwed into a corresponding threaded borehole of a housing. A flat hexagonal collar 18 as a key projection is located between the threading 16 and the external threading 17.

At its lower end, i.e., at the end away from the hexagonal collar 18, the base body 15 is provided with a plurality of claws 19 pointing in the axial direction. The claws 19 form a rim that is coaxial to the external threading 17. This is coaxial, in turn, to the external threading 16, and the hexagonal collar 18 is also arranged coaxial to both.

A cylindrical borehole 21 that is coaxial to the threadings 16, 17, as well as the rim of claws 19 leads through the base body 15. The claws 19 define a cylindrical opening 22 whose diameter is somewhat larger than the diameter of the borehole 21, with their surfaces pointing inward in the radial direction, wherein a shoulder surface 23 is produced at which the borehole 21 ends. The opening 22 is used as a seat for an elastomer seal 24 that has the shape of a smooth-walled, cylindrical pipe piece with an opening 25.

The inner diameter of the borehole 25 corresponds to the outer diameter of the cylindrical housing section 6 on the bus component 1. For interlocking the claws 19, a coupling ring 26 is provided whose construction does not need to be explained further. In practice, the ring 26 is screwed onto the threading 17. Finally, an elastomer flat seal 27 is also provided that lies in the assembled state between the top side of the hexagonal collar 18 and the relevant housing wall.

The use or application and the assembly is as follows: The PG screw connection 2 is screwed tightly to a housing wall, not shown further, with the elastomer flat seal 27 arranged between them, wherein the external threading 16 is screwed into the corresponding threading borehole of the housing. With the help of the flat seal 27, the necessary sealing according to IP 64 is achieved.

The PG screw connection 2 may be preassembled by the supplier, i.e., the rubber seal 24 is inserted between the claws 19 and the coupling ring 26 is screwed onto the external threading 17. It is initially screwed on only so far that the claws 19 are not bent inward in the radial direction with their free ends. In the PG screw connection 2 prepared or preassembled in this way, the bus terminating component with the conical section 8 is inserted first with the terminal wires 12, 13 in front. In the inserted state, the cylindrical section 6 sits in the elastomer seal 24. The insulated terminal wires 12, 13 are led through the PG screw connection 2 into the interior of the housing to be placed and can be positioned there on the corresponding clamping devices.

After insertion of the bus termination component 1, the coupling ring 26 is screwed tight. A frustum-like surface contained in the coupling ring 26 presses the claws 19 radially inward, wherein the rubber seal 24 is pressed against the cylindrical section 6 of the bus component 1. In this way, on one hand, the bus component 1 is held mechanically in the PG screw connection and, on the other hand, the required sealing according to IP 64 is achieved.

The bus terminating component 1 is thus affixed on the housing in a way sufficient for the installation specifications, without requiring a large housing that can be locked onto a top hat rail. In a practical embodiment, the outer diameter of the cylindrical section 6 is about 11.5 mm, thus corresponding to the nominal diameter of the corresponding PG screw connection and reaching completely through the seal 24. The length of the cylindrical section 7 is about 16 mm. The cylindrical section 7 has a length of about 10 mm. Clearly, the required housing is very small.

FIG. 2 shows the electrical configuration in an embodiment of the invention. The two terminal wires 12, 13 are connected in the interior of the housing 3 to a series circuit made from a total of 3 capacitors 31, 32, and 33 and also from a bus terminating resistor 34 lying in series with this circuit. The nominal value of the ohmic bus terminating resistor 34 corresponds to the characteristic wave resistance of the bus line to be terminated in the relevant frequency range. In a practical embodiment, it lies between 50 and 100 Ohms.

The capacitors 31-33 lying in series with this circuit are ceramic capacitors, each with a capacitance of 3.3 μF and a withstand voltage of 50 Volts in an embodiment of the invention. Because the capacitance for ceramic capacitors is dependent within certain limits on the applied voltage, a cascade made from ohmic resistors 35, 36, 37 lies parallel to the cascade made from the capacitors 31-33 and indeed so that a resistor 35, 37 is connected in parallel to each capacitor. The resistors 35-37 each have the same values. This also applies for the capacitors 31-33. The resistance value of the balancing resistors 35-37 is large relative to the resistance value of the bus terminating resistor 34, wherein the bus terminating component 1 features a large impedance for a direct-current voltage between the terminals 12 and 13. The impedance lies at around 6.6 MΩ in an embodiment of the invention.

The cascade made from the three capacitors 31-33 has a very small impedance of <21 Ohms for the frequency range of interest. In practice, only the resistance value of the bus terminating resistor 34 is visible. For the transmission frequency range, only the resistance of the bus terminating resistor 34 is decisive, while for the direct-current voltage that is applied on the bus lines and that is used not only for the signal transmission, but also for the power supply, the large impedance made from the series circuit of the resistors 34-37 is active. The current generated in this way through the resistor cascade lies at about 5 μA. Practically no relevant power loss that would require special cooling occurs on the components.

For this reason, all of the electronic components can be easily held in the small housing 3 of the bus component according to FIG. 1. The insulated, single-pole terminal wires 12, 13 that are constructed as insulated strands with a diameter of 0.75 mm and that are led out from the housing 3 have the largest diameter.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

Recitations of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

1-14. (canceled)

15. A bus terminating component comprising:
a cylindrical housing that forms a housing interior;
a stop shoulder arranged on the housing;
electrical components are arranged in the housing interior suitable for terminating a bus with low reflection;
a sealing compound that seals at least to the outside or preferably predominantly or completely fills the housing interior; and
two terminal wires leading out from the housing interior.

16. The bus terminating component according to claim 15, wherein the cylindrical housing is made from plastic or metal.

17. The bus terminating component according to claim 15, wherein the cylindrical housing is tapered in a frustum-like shape at the end at which the connection carriers emerge.

18. The bus terminating component according to claim 15, wherein the housing has a head at the end opposite the open end.

19. The bus terminating component according to claim 15, wherein the head is rotationally symmetric.

20. The bus terminating component according to claim 15, wherein the head is arranged coaxial to the other housing.

21. The bus terminating component according to claim 20, wherein the head is closed at the end face such that the housing interior is closed like a blind hole.

22. The bus terminating component according to claim 20, wherein the stop shoulder is formed by a shoulder in which the head transitions into the other housing.

23. The bus terminating component according to claim 20, wherein, outside of the head, the housing has a diameter that corresponds to the nominal diameter of a PG screw connection .

24. The bus terminating component according to claim 15, wherein the component has an overall explosion-proof construction.

25. The bus terminating component according to claim 15, wherein the component satisfies at least one of the ignition protection category flameproof enclosure ex d, the encapsulation ex m and the intrinsic safety ex e.

26. A bus terminating component with an explosion-proof construction comprising:
an ohmic terminating resistor whose resistance value corresponds to the characteristic wave impedance of the line to be terminated; and
at least one capacitor lying in series with the terminating resistor.

27. The bus terminating component according to claim 26, wherein three capacitors are connected in series with the terminating resistor.

28. The bus terminating component according to claim 27, wherein a balancing resistor is connected in parallel to each capacitor, wherein the resistance value of the balancing resistor is large relative to the resistance value of the terminating resistor.
